(19) United States
(12) Patent Application Publication
(10) Pub. No.: US 2013/0020673 A1
(43) Pub. Date: Jan. 24, 2013

(54) PROTECTION DIODE AND SEMICONDUCTOR DEVICE HAVING THE SAME

(71) Applicants: Atsushi HIRAMA, Tokyo (JP); Masahiko Higashi, Ibaraki (JP)

(72) Inventors: Atsushi HIRAMA, Tokyo (JP); Masahiko Higashi, Ibaraki (JP)

(21) Appl. No.: 13/547,496

(22) Filed: Jul. 12, 2012

(30) Foreign Application Priority Data
Jul. 20, 2011 (JP) 2011-158929

(51) Int. Cl. H01L 27/08

(52) U.S. Cl. 257/506; 257/499; 257/E27.051

(57) ABSTRACT

A protection diode includes a semiconductor substrate having a first region, a second region surrounding the first region, and a third region surrounding the second region; a first insulation layer disposed between the second region and the third region; a first conductive type semiconductor portion disposed in the third region; a second conductive type semiconductor portion disposed in the second region; and a capacity reduction layer disposed in the first region.

### BACKGROUND OF THE INVENTION AND RELATED ART STATEMENT

The present invention relates to a protection diode and a semiconductor device having the same. More specifically, the present invention relates to a protection diode capable of protecting an internal circuit of a semiconductor device against an excessive input voltage.

In a conventional semiconductor device such as a drive IC and the like, a conventional protection diode is disposed at a signal input terminal thereof for protecting an internal circuit of the conventional semiconductor device against an excessive input voltage.

Patent Reference 1 has disclosed such a conventional semiconductor device having the conventional protection diode. The conventional protection diode is formed of, for example, a PN connection diode produced through a process for implanting an N-type semiconductor into a P-type well.

Patent Reference 2 has disclosed such an input conventional protection diode having the configuration described above.

Patent Reference 1: Japanese Patent Publication No. 2010-123796

Patent Reference 2: Japanese Patent Publication No. 06-350034

In general, in the PN connection diode, a PN connection capacity is generated at a connection portion of a P-type semiconductor portion and an N-type semiconductor portion. Accordingly, when a large capacity exists in a signal transmission path, a signal wave form tends to be deformed to a larger extent. As a result, it is desirable to reduce a PN connection capacity of a protection diode disposed at a signal input terminal for inputting a high speed signal. However, in the conventional protection diode, it is difficult to reduce the PN connection capacity thereof disposed at the signal input terminal for inputting the high speed signal.

In view of the problems described above, an object of the present invention is to provide a protection diode capable of solving the problems of the conventional protection diode. In the present invention, it is possible to reduce the PN connection capacity thereof disposed at a signal input terminal for inputting a high speed signal.

Further objects and advantages of the invention will be apparent from the following description of the invention.

### SUMMARY OF THE INVENTION

In order to attain the objects described above, according to a first aspect of the present invention, a protection diode includes a semiconductor substrate having a first region, a second region surrounding the first region, and a third region surrounding the second region; a first insulation layer disposed between the second region and the third region; a first conductive type semiconductor portion disposed in the third region; a second conductive type semiconductor portion disposed in the second region; and a capacity reduction layer disposed in the first region.

According to a second aspect of the present invention, a semiconductor device includes a first protection diode, a second protection diode, a first pad, and a second pad.

According the second aspect of the present invention, the first protection diode includes a semiconductor substrate having a first region, a second region surrounding the first region, and a third region surrounding the second region; a first insulation layer disposed between the second region and the third region; a first conductive type semiconductor portion disposed in the third region; a second conductive type semiconductor portion disposed in the second region; and a capacity reduction layer disposed in the first region.

According the second aspect of the present invention, the second protection diode includes a semiconductor substrate having a fourth region, a fifth region surrounding the fourth region, and a sixth region surrounding the fifth region; a third insulation layer disposed between the fifth region and the sixth region; a first conductive type semiconductor portion disposed in the sixth region; and a second conductive type semiconductor portion disposed in the fourth region and the fifth region.

According the second aspect of the present invention, the first pad is connected to the second protection diode for inputting and outputting a first signal with a first frequency. The second pad is connected to the first protection diode for inputting and outputting a second signal with a second frequency higher than the first frequency.

In the present invention, it is possible to reduce a PN connection capacity of the protection diode and the second conductor device.

### BRIEF DESCRIPTION OF THE DRAWINGS

FIG. 1 is a schematic plan view showing a configuration of a protection diode according to a first embodiment of the present invention;

FIG. 2 is a schematic sectional view showing the configuration of the protection diode taken along a line A-A in FIG. 1 according to the first embodiment of the present invention;

FIG. 3 is a schematic sectional view showing the configuration of the protection diode in which a PN connection capacity and a forward direction current path are presented according to the first embodiment of the present invention;

FIG. 4 is a schematic plan view showing a configuration of a protection diode according to a second embodiment of the present invention;

FIG. 5 is a schematic sectional view showing the configuration of the protection diode taken along a line B-B in FIG. 4 according to the second embodiment of the present invention;

FIG. 6 is a schematic sectional view showing the configuration of the protection diode in which a PN connection capacity and a forward direction current path are presented according to the second embodiment of the present invention;

FIG. 7 is a schematic view showing a configuration of a semiconductor device according to a third embodiment of the present invention;

FIG. 8 is a schematic plan view showing a configuration of a second protection diode according to the third embodiment of the present invention; and

FIG. 9 is a schematic sectional view showing the configuration of the second protection diode taken along a line C-C in FIG. 8 according to the third embodiment of the present invention.

### DETAILED DESCRIPTION OF PREFERRED EMBODIMENTS

Hereunder, preferred embodiments of the present invention will be explained with reference to the accompanying drawings.

### First Embodiment

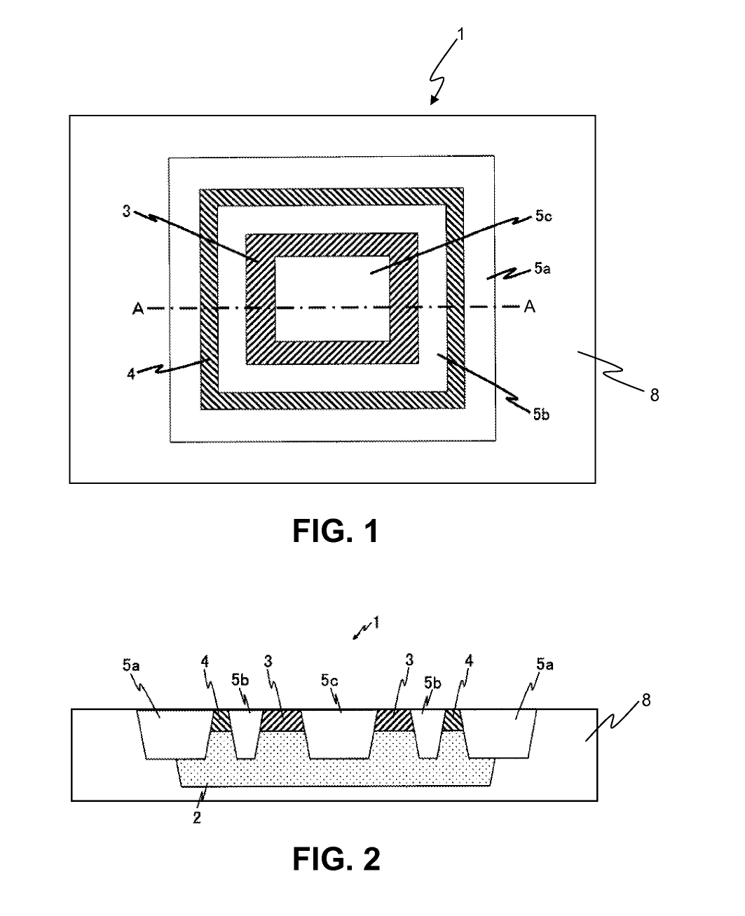

A first embodiment of the present invention will be explained. FIG. 1 is a schematic plan view showing a configuration of a protection diode 1 according to the first embodiment of the present invention. FIG. 2 is a schematic sectional view showing the configuration of the protection diode 1 taken along a line A-A in FIG. 1 according to the first embodiment of the present invention.

As shown in FIG. 1, the protection diode 1 includes a semiconductor substrate 8 formed of silicon and the like, and a P-type well 2 is formed in the semiconductor substrate 8. Further, the protection diode 1 includes a P-type semiconductor layer 4 and an N-type semiconductor layer 3 formed in the P-type well 2. The P-type semiconductor layer 4 and the N-type semiconductor layer 3 are arranged such that the P-type semiconductor layer 4 is situated at a position outside the N-type semiconductor layer 3 with a specific distance in between.

In the embodiment, an element separation portion 5b formed of an insulation material is disposed between the N-type semiconductor layer 3 and the P-type semiconductor layer 4 for separating the N-type semiconductor layer 3 from the P-type semiconductor layer 4. The N-type semiconductor layer 3 has an opening portion at a center portion thereof, so that the N-type semiconductor layer 3 is formed in, for example, a rectangular frame shape or a ring shape.

In the embodiment, an element separation portion 5a is formed in the P-type well 2 to surround an outer circumference of the P-type semiconductor layer 4, so that the element separation portion 5a separates the P-type semiconductor layer 4 from an element (not shown) disposed outside the P-type semiconductor layer 4. Further, an element separation portion 5c is disposed at the center portion of the N-type semiconductor layer 3. The element separation portion 5a, the element separation portion 5b, and the element separation portion 5c are formed through a process such as, for example, STI (Shallow Trench Isolation) or LOCOS (Local Oxidation of Silicon).

In the embodiment, a region where the element separation portion 5c is situated is defined as a first region of the semiconductor substrate 8; a region where the N-type semiconductor layer 3 is situated is defined as a second region of the semiconductor substrate 8; and a region where the P-type semiconductor layer 4 is situated is defined as a third region of the semiconductor substrate 8. Accordingly, the second region surrounds the first region, and the third region surrounds the second region. Further, the element separation portion 5b is disposed between the second region and the third region as a first insulation layer, and the element separation portion 5c is disposed as a second insulation layer. It is defined that the P-type is the first conductive type, and the N-type is the second conductive type.

In the embodiment, the P-type semiconductor layer 4 corresponds to an anode of the protection diode 1, and the N-type semiconductor layer 3 corresponds to a cathode of the protection diode 1. In the protection diode 1, when a positive voltage is applied to the P-type semiconductor layer 4 and a negative voltage is applied to the N-type semiconductor layer 3, a forward direction current flows from the P-type semiconductor layer 4 to the N-type semiconductor layer 3. In an actual configuration, for example, the P-type semiconductor layer 4 is connected to a signal input terminal of a semiconductor device, and the N-type semiconductor layer 3 is connected to a ground potential.

In the embodiment, a metal wiring portion and the like (not shown) may be formed on the N-type semiconductor layer 3, the P-type semiconductor layer 4, the element separation portion 5a, the element separation portion 5b, and the element separation portion 5c for connecting to an interlayer insulation film, a signal input terminal, a power source potential, and a ground potential. It is noted that the metal wiring portion is omitted in the drawings. It is also noted that the protection diode 1 may produced through an ordinary semiconductor manufacturing technique such as lithography, ion implantation, and the like.

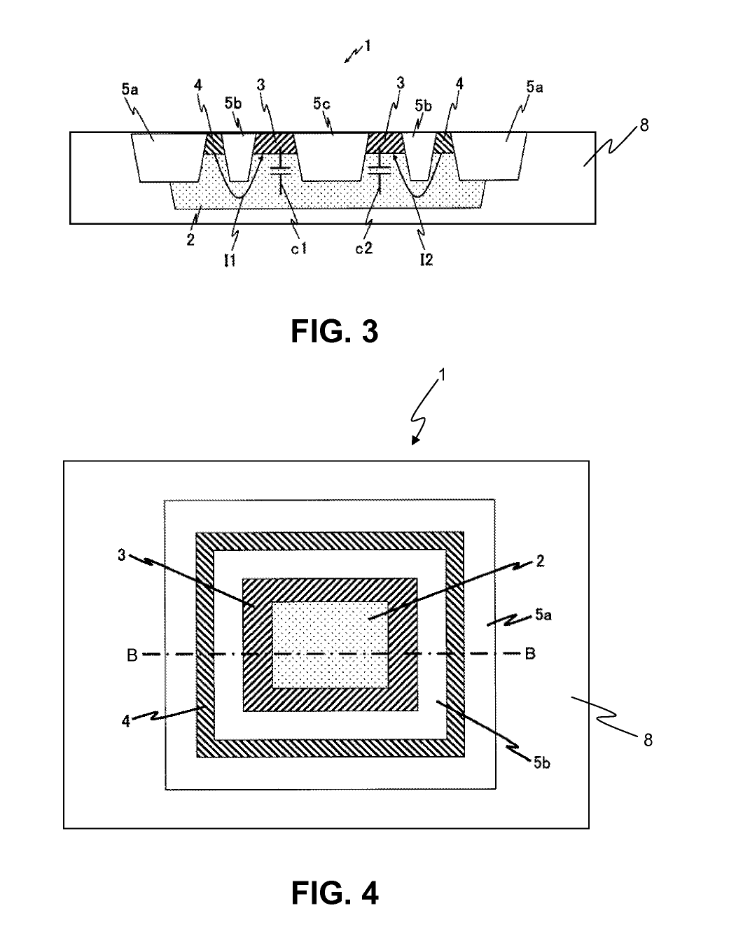

FIG. 3 is a schematic sectional view showing the configuration of the protection diode 1 in which PN connection capacities C1 and C2 and forward direction current paths I1 and I2 are presented according to the first embodiment of the present invention.

As shown in FIG. 3, the PN connection capacities C1 and C2 are generated at a connection portion between the N-type semiconductor layer 3 and the P-type well 2. As described above, the N-type semiconductor layer 3 is formed in the rectangular frame shape or the ring shape, and is situated only near the element separation portion 5b. Accordingly, as opposed to the case when the N-type semiconductor layer 3 is formed in, for example, a plane shape, it is possible to reduce a size of the connection portion between the N-type semiconductor layer 3 and the P-type well 2. As a result, the PN connection capacities C1 and C2 are decreased.

As explained above, in the embodiment, when the element separation portion 5c is disposed in the first region, it is possible to reduce the PN connection capacities C1 and C2. Accordingly, the element separation portion 5c is defined as a capacity reduction layer. As opposed to the case that the N-type semiconductor is disposed in the first region, when the capacity reduction layer is disposed in the first region, it is possible to reduce the PN connection capacities C1 and C2 generated between the N-type semiconductor layer 3 and the P-type well 2. Further, when the element separation portion 5c is disposed inside the ring shape of the N-type semiconductor layer 3, it is possible to securely prevent the PN connection capacity from being generated inside the ring shape of the N-type semiconductor layer 3.

In the embodiment, when a forward direction bias is applied to the protection diode 1 in the forward direction, the forward direction currents I1 and I2 flow from the P-type semiconductor layer 4 to the N-type semiconductor layer 3. At this moment, the forward direction currents I1 and I2 cannot pass through the element separation portion 5b, so that the forward direction currents I1 and I2 pass through the P-type well 2. It is noted that the P-type well 2 has an impurity concentration smaller than an impurity concentration of the N-type semiconductor layer 3, so that the P-type well 2 has a resistivity value higher than a resistivity value of the N-type semiconductor layer 3. Accordingly, after the forward direction currents I1 and I2 flow into the P-type well 2 from the P-type semiconductor layer 4, the forward direction currents I1 and I2 flow into the N-type semiconductor layer 3 arranged near the element separation portion 5b. More specifically, the forward direction currents I1 and I2 flow into a peripheral portion of the N-type semiconductor layer 3

It is noted that, as opposed to the protection diode 1 in the embodiment, when the size of the N-type semiconductor layer 3 is decreased while maintaining the plane shape thereof, it is still possible to reduce the ON connection capacity. However, in this case, the peripheral portion of the N-type semiconductor layer 3 tends to have a higher resistivity. Accordingly, when the forward direction currents I1 and I2 flow into the peripheral portion of the N-type semiconductor layer 3, it is difficult to smoothly flow an excessive current.

On the other hand, in the protection diode 1 in the embodiment, the N-type semiconductor layer 3 is formed in, for example, the ring shape arranged adjacent only to the element separation portion 5b. As a result, it is possible to reduce the PN connection capacity without increasing the resistivity of the peripheral portion of the N-type semiconductor layer 3, through which the forward direction currents I1 and I2 flow. It is noted that the protection diode 1 has the PN connection capacity thus reduced, so that the protection diode 1 is effectively used in an input terminal of a high speed signal.

As explained above, in the protection diode 1 in the embodiment, it is possible to flow a sufficient amount of the excessive current while reducing the PN connection capacity.

### Second Embodiment

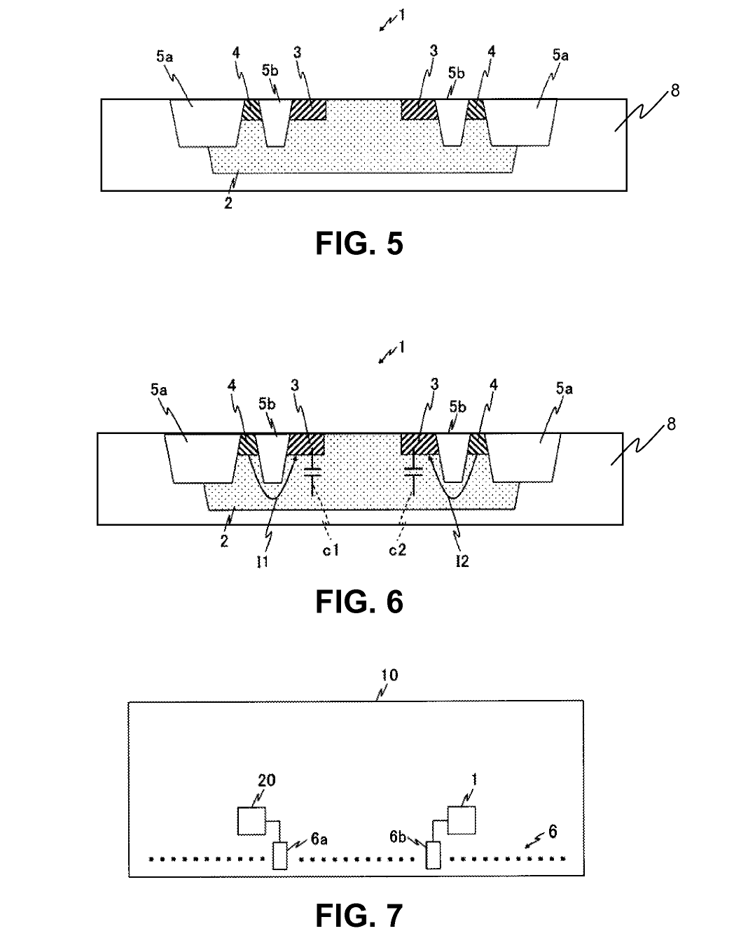

A second embodiment of the present invention will be explained next. FIG. 4 is a schematic plan view showing a configuration of the protection diode 1 according to the second embodiment of the present invention. FIG. 5 is a schematic sectional view showing the configuration of the protection diode 1 taken along a line B-B in FIG. 4 according to the second embodiment of the present invention. In the following description, a difference from the first embodiment will be mainly explained.

As shown in FIG. 4, different from the first embodiment, the element separation portion 5c is not disposed inside the N-type semiconductor layer 3. Instead, the P-type well 2 is disposed inside the N-type semiconductor layer 3. Accordingly, the P-type well 2 is arranged to function as the capacity reduction layer. Other configuration of the protection diode 1 in the second embodiment is similar to that of the protection diode 1 in the first embodiment. It is noted that the P-type well 2 has an impurity concentration smaller than the impurity concentration of the P-type semiconductor layer 4.

FIG. 6 is a schematic sectional view showing the configuration of the protection diode 1 in which the PN connection capacities C1 and C2 and the forward direction current paths I1 and I2 are presented according to the second embodiment of the present invention.

As shown in FIG. 6, similar to the first embodiment, the PN connection capacities C1 and C2 are generated at a connection portion between the N-type semiconductor layer 3 and the P-type well 2. As described above, the N-type semiconductor layer 3 is formed in the rectangular frame shape or the ring shape and situated only near the element separation portion 5b. Accordingly, it is possible to reduce the PN connection capacities C1 and C2.

As explained above, in the second embodiment, the element separation portion 5c is not disposed inside the N-type semiconductor layer 3. Accordingly, similar to the conventional configuration, in which only the element separation portion 5a and the element separation portion 5b are disposed in the P-type well 2 as the element separation portion, it is possible to produce the protection diode 1 just through slightly changing a shape of a photo resist mask used in the photolithography process.

As explained above, in the first embodiment and the second embodiment, the N-type semiconductor layer 3 and the P-type semiconductor layer 4 are disposed in the P-type well 2. The present invention is not limited to the configuration. Alternatively, the locations of the N-type semiconductor layer 3 and the P-type semiconductor layer 4 may be switched, and the N-type semiconductor layer 3 and the P-type semiconductor layer 4 may be disposed in the P-type well 2. In this case, it is still possible to obtain the similar effect.

As explained above, in the first embodiment and the second embodiment, the N-type semiconductor layer 3 is formed in the rectangular frame shape or the ring shape. The present invention is not limited to the configuration. Alternatively, the N-type semiconductor layer 3 may be formed in a shape not closed in the ring shape such as a C character shape with an opening portion at a center portion thereof. In this case, it is still possible to obtain the similar effect.

### Third Embodiment

A third embodiment of the present invention will be explained next. FIG. 7 is a schematic view showing a configuration of a semiconductor device 10 according to the third embodiment of the present invention.

In the second embodiment, the semiconductor device 10 may be a semiconductor chip such as an LSI (Large Scale Integrated circuit) and the like. As shown in FIG. 7, the semiconductor device 10 includes the protection diode 1 as a first protection diode; a protection diode 20 as a second protection diode; and a pad group 6 for inputting and outputting various signals. The pad group 6 is formed of a plurality of pads connected to various components.

In the embodiment, the pad group 6 includes a pad 6a connected to the protection diode 20 for inputting and outputting a signal having a relatively low frequency (a first frequency). It is noted that the protection diode 20 is not provided with the capacity reduction layer. Further, the pad group 6 includes a pad 6b connected to the protection diode 1 for inputting and outputting a signal having a second frequency higher than the first frequency.

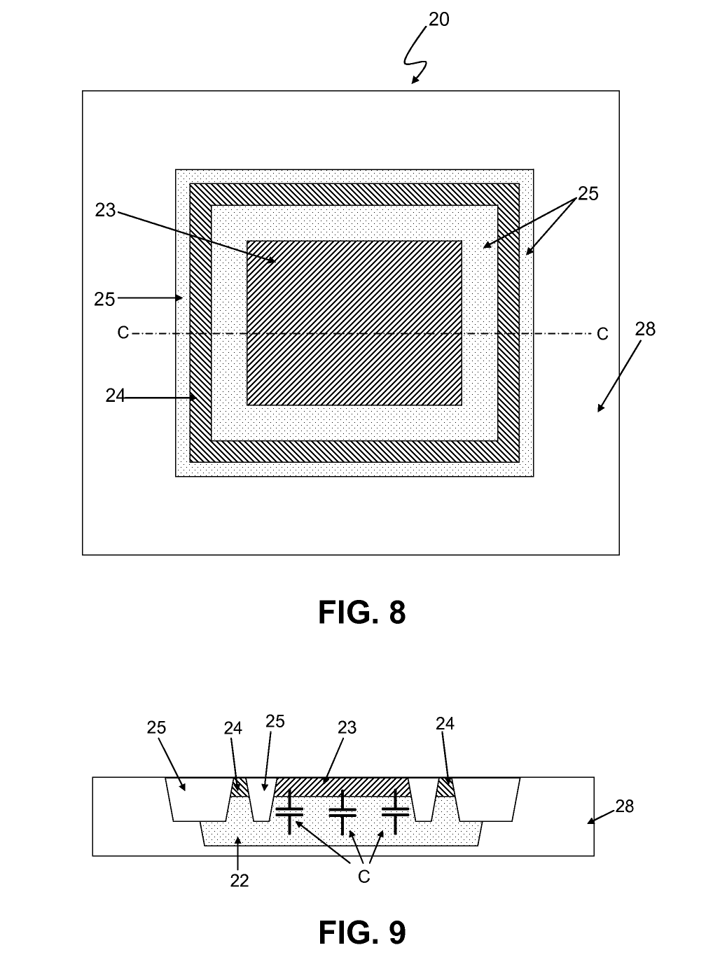

FIG. 8 is a schematic plan view showing a configuration of the second protection diode 20 according to the third embodiment of the present invention. FIG. 9 is a schematic sectional view showing the configuration of the second protection diode 20 taken along a line C-C in FIG. 8 according to the third embodiment of the present invention.

As shown in FIG. 8, the protection diode 20 includes a semiconductor substrate 28 formed of silicon and the like, and a P-type well 22 is formed in the semiconductor substrate 8. Further, the protection diode 20 includes a P-type semiconductor layer 24 and an N-type semiconductor layer 23 formed in the P-type well 22. The P-type semiconductor layer 24 and the N-type semiconductor layer 23 are arranged such that the P-type semiconductor layer 24 is situated at a position outside the N-type semiconductor layer 23 with a specific distance in between.

In the embodiment, an insulation layer 25 formed as a third insulation layer through a process such as, for example, STI (Shallow Trench Isolation), is disposed between the N-type semiconductor layer 23 and the P-type semiconductor layer 24 for separating the N-type semiconductor layer 23 and the P-type semiconductor layer 24. Different from the protection diode 1, in the protection diode 20, the N-type semiconductor layer 23 does not have an opening portion at a center portion thereof, so that the N-type semiconductor layer 3 is formed in, for example, a rectangular shape or a square shape.

In the embodiment, the insulation layer 25 is also formed in the P-type well 2 to surround an outer circumference of the P-type semiconductor layer 24, so that the insulation layer 25 separates the P-type semiconductor layer 24 from an element (not shown) disposed outside the P-type semiconductor layer 24.

In the embodiment, a region where the N-type semiconductor layer 23 is situated is defined as a fourth region of the semiconductor substrate 28; a region where the insulation layer 25 is situated between the N-type semiconductor layer 23 and the P-type semiconductor layer 24 is defined as a fifth region of the semiconductor substrate 8; and a region where the P-type semiconductor layer 24 is situated is defined as a sixth region of the semiconductor substrate 28. Accordingly, the fifth region surrounds the fourth region, and the sixth region surrounds the fifth region. It is defined that the P-type is the first conductive type, and the N-type is the second conductive type.

As explained above, in the embodiment, specific ones of the pad group 6 such as the pad 6b are connected to the protection diode 1 for inputting and outputting a signal having a relatively high frequency.

The disclosure of Japanese Patent Application No. 2011-158929, filed on Jul. 20, 2011, is incorporated in the application by reference.

While the invention has been explained with reference to the specific embodiments of the invention, the explanation is illustrative and the invention is limited only by the appended claims.

What is claimed is:

1. A protection diode, comprising:
a semiconductor substrate having a first region, a second region surrounding the first region, and a third region surrounding the second region;
a first insulation layer disposed between the second region and the third region;
a first conductive type semiconductor portion disposed in the third region;
a second conductive type semiconductor portion disposed in the second region; and
a capacity reduction layer disposed in the first region.

2. The protection diode according to claim 1, wherein said capacity reduction layer is configured to reduce a connection capacity of the first conductive type semiconductor lower than a case that the second conductive type semiconductor is disposed in the first region.

3. The protection diode according to claim 1, wherein said capacity reduction layer is formed of a second insulation layer.

4. The protection diode according to claim 1, wherein said capacity reduction layer is formed of a second insulation layer constituting an STI (Shallow Trench Isolation).

5. The protection diode according to claim 1, wherein said capacity reduction layer is formed of a material containing the first semiconductor at a concentration lower than that of the first conductive type semiconductor portion.

6. The protection diode according to claim 1, wherein one of said first conductive type semiconductor portion and said second conductive type semiconductor portion is arranged to function as an anode, and the other of said first conductive type semiconductor portion and said second conductive type semiconductor portion is arranged to function as a cathode.

7. A semiconductor device comprising:
a first protection diode;
a second protection diode;
a first pad; and
a second pad.
wherein said first protection diode includes,
a first semiconductor substrate having a first region, a second region surrounding the first region, and a third region surrounding the second region;
a first insulation layer disposed between the second region and the third region;
a first conductive type semiconductor portion disposed in the third region;
a second conductive type semiconductor portion disposed in the second region; and
a capacity reduction layer disposed in the first region,
said second protection diode includes
a second semiconductor substrate having a fourth region, a fifth region surrounding the fourth region, and a sixth region surrounding the fifth region;
a third insulation layer disposed in the fifth region;
a first conductive type semiconductor layer disposed in the sixth region; and
a second conductive type semiconductor layer disposed in the fourth region,
wherein said first pad is connected to the second protection diode for inputting and outputting a first signal with a first frequency, and
said second pad is connected to the first protection diode for inputting and outputting a second signal with a second frequency higher than the first frequency.

8. A protection diode, comprising:
a semiconductor substrate;
a first conductive type semiconductor well;
a first conductive type semiconductor portion disposed in the first conductive type semiconductor well;
a second conductive type semiconductor portion disposed in the first conductive type semiconductor well inside the first conductive type semiconductor portion and having an opening portion at a center portion thereof; and
a first insulation layer disposed between the first conductive type semiconductor portion and the second conductive type semiconductor portion.

9. The protection diode according to claim 8, wherein said second conductive type semiconductor portion is formed in a frame shape or a ring shape.

10. The protection diode according to claim 8, further comprising a second insulation layer disposed inside the second conductive type semiconductor portion.
